(19) United States
(12) Patent Application Publication
(10) Pub. No.: US 2025/0234497 A1
(43) Pub. Date: Jul. 17, 2025

(54) INVERTER DEVICE, ELECTRIC DRIVE AND VEHICLE

(71) Applicant: Valeo eAutomotive Germany GmbH, Erlangen (DE)

(72) Inventors: Ishwar LONDHE, Erlangen (DE); Kay PFEIFFER, Erlangen (DE); Emil THOMAS, Chennai (IN); Alexandros KOURGIALIS, Erlangen (DE)

(73) Assignee: Valeo eAutomotive Germany GmbH, Erlangen (DE)

(21) Appl. No.: 19/016,826

(22) Filed: Jan. 10, 2025

(30) Foreign Application Priority Data
Jan. 12, 2024 (DE) 102024100884.9

(51) Int. Cl. H05K 7/20; B60K 11/02; B60L 15/00; H02M 7/00

(52) U.S. Cl. CPC H05K 7/2089; B60K 11/02; B60L 15/007; H02M 7/003

(57) ABSTRACT

An inverter device includes a capacitor assembly, an inverter circuit, and a cooling device having a cooling channel connecting an inlet and an outlet in a fluid-conductive manner, and a heat exchange body on which semiconductor switching modules of the inverter circuit are mounted for heat exchange with the coolant. A housing structure includes multiple side walls, a base wall, and a top wall section limiting defining an accommodation space. A cavity is formed on a first side of the top wall section and limits the cooling channel together with the heat exchange body. The capacitor assembly is arranged inside the accommodation space and is thermally connected to the cooling device by a heat transfer means arranged between the capacitor assembly and the second side of the top wall section for heat exchange with the coolant.

The present invention relates to an inverter device. Aside, the invention relates to an electric drive and a vehicle.

In automotive applications, inverter devices serve to convert a DC voltage into a multiphase AC voltage for supplying an electric machine. On its DC link, the inverter device is equipped with a capacitor assembly. The DC link is connected to an inverter circuit, which comprises semiconductor switching modules. It is generally known to provide a cooling device with a heat exchange body, on which the semiconductor switching modules are mounted so as to be cooled by a coolant flow along a cooling channel.

It is an object of the present invention to provide an improved inverter device for automotive applications.

According to the invention, the above object is solved by an inverter device for an electric vehicle, the inverter device comprising: a capacitor assembly; an inverter circuit comprising multiple semiconductor switching modules; a cooling device having an inlet for a coolant, an outlet for the coolant, a cooling channel connecting the inlet and the outlet in a fluid-conductive manner and a heat exchange body, on which the semiconductor switching modules are mounted for heat exchange with the coolant; and a housing structure comprising multiple side wall sections surrounding an accommodation space, a base wall section closing the accommodation space on one end of the side wall sections and a top wall section limiting the accommodation space on another end of the side wall sections; wherein a cavity is formed on a first side of the top wall section, the cavity limiting the cooling channel together with the heat exchange body; wherein the capacitor assembly is arranged inside the accommodation space such that a second side of the top wall section faces the capacitor assembly and that the cavity partially overlies the capacitor assembly; wherein the capacitor assembly is thermally connected to the cooling device by a heat transfer means arranged between the capacitor assembly and the second side of the top wall section for heat exchange with the coolant.

The inverter device according to the invention comprises a capacitor assembly, an inverter circuit, a cooling device and a housing structure. The inverter circuit comprises multiple semiconductor switching modules. The cooling device has an inlet for a coolant, an outlet for the coolant, a cooling channel and a heat exchange body. The cooling channel connects the inlet and the outlet in a fluid-conductive manner. On the heat exchange body, the semiconductor switching modules are mounted for heat exchange with the coolant.

The housing structure comprises multiple side wall sections, a base wall section and a top wall section. The side wall sections surround an accommodation space. The base wall section closes the accommodation space on one end of the side wall sections. The top wall section limits the accommodation space on another end of the side wall sections. A cavity is formed on a first side of the top wall section. The cavity limits the cooling channel together with the heat exchange body. The capacitor assembly is arranged inside the accommodation space such that a second side of the top wall section faces the capacitor assembly and that the cavity partially overlies the capacitor assembly. The capacitor assembly is thermally connected to the cooling device by a heat transfer means. The heat transfer means is arranged between the capacitor assembly and the second side of the top wall section for heat exchange with the coolant.

The invention is based upon the consideration to use the cooling device for cooling the capacitor assembly as well as the inverter circuit. Thereto, the capacitor assembly and the inverter circuit are arranged on the opposite first and second sides of the top wall section.

Advantageously, such an arrangement allows to use a single cooling device instead of separate ones for the inverter circuit and the capacitor assembly.

Further, the bulky capacitor assembly can be disposed inside the inverter device in a less space-consuming way.

The capacitor assembly may comprise multiple capacitor elements disposed inside a housing. The capacitor assembly may have a capacitance of at least 400 μF, preferably at least 600 μF, more preferably at least 750 μF.

The heat transfer means may be a gap filler. A gap filler is a material with good heat transfer properties. During application the gap filler is fluid and makes a tight connection between the surface of the capacitor assembly and the housing structure. Later on, the gap filles cures.

The switching modules of the inverter circuit may each comprise switching elements connected into half-bridges, where each half-bridge is connected in parallel to the capacitor assembly. The switching elements may be IGBTs or power MOSFETs.

Preferably, the semiconductor switching modules are mounted on the heat exchange body by soldering or sintering. This allows a good heat conductivity between the switching modules and the cooling device.

Advantageously, the heat exchange body is formed by multiple stacked meander plates and a carrier plate stacked on the meander plate, the semiconductor switching modules being mounted on the carrier plate. The usage of meander plates increases the surface of the heat exchange body in contact with the coolant and, therefore, increases the cooling performance. Further, the meander plates cause the coolant to mix up so as to avoid “dead water” regions along the cooling channel. The meander plates and/or the carrier plate may be made by brazing and/or may be made of aluminum.

Optionally, the heat exchange body is removably fastened upon the first side of the top wall section, therein closing the cavity.

Preferably, the capacitor assembly is removably fastened to the one or multiple of the wall sections in the accommodation space. This allows a rigid connection between the housing structure and the capacitor assembly, which decreases vibrations during the use of the inverter device in a driving vehicle. Particularly, the housing of the capacitor assembly is screwed to the housing structure.

In a preferred embodiment, the top wall section comprises an opening, through which electrical connections between the capacitor assembly and a DC terminal of the inverter circuit are guided. Especially, the opening is oblong with a long side extending in along a coolant main flow direction of cooling channel. The main flow direction may be a direction from the inlet to the outlet.

In order to allow a high degree of maintainability, the base wall section my be realized by a cover plate removably fastened to the housing structure.

Advantageously, the inverter device according to the invention further comprises a printed circuit board, the semiconductor switching modules being arranged between the cavity and the printed circuit board. The printed circuit board may carry control electronics for the inverter circuit.

In a preferred design, the top wall section comprises mounting domes extending from its first side beyond the semiconductor switching modules, the printed circuit board being mounted on the mounting domes. The mounting domes may be formed integrally with the housing structure or may be mounted thereon.

The inverter device according to the invention may further comprise an inlet connector for supplying the coolant and an outlet connector for draining the coolant. Therein, the inlet connector may be connected to the inlet of the cooling channel by tubes formed within the housing structure. Alternatively or additionally, the outlet connector may be connected to the outlet of the cooling channel by tubes formed within the housing structure.

The above object is further solved by an electric drive for driving a vehicle, the electric drive comprising: a rotating electric machine; and an inverter device according to the invention; wherein the inverter device is configured to supply a multiphase AC current to the electric machine.

The electric machine may be a synchronous motor, in particular a permanent magnet or electrically excited synchronous motor. Alternatively, the electric machine may be an induction motor.

The electric drive according to the invention preferably comprises a machine housing, inside which the electric machine is accommodated, wherein the housing structure of the inverter device is removably fastened to the machine housing.

The above object is further solved by a vehicle, comprising an electric drive according to the invention.

The vehicle may be a battery electric vehicle, a fuel-cell supplied electric vehicle or a hybrid vehicle. In case of the hybrid vehicle an additional combustion engine is provided.

Further details and advantages of the invention are disclosed in the following, wherein reference is made to the drawing. The drawings show schematically:

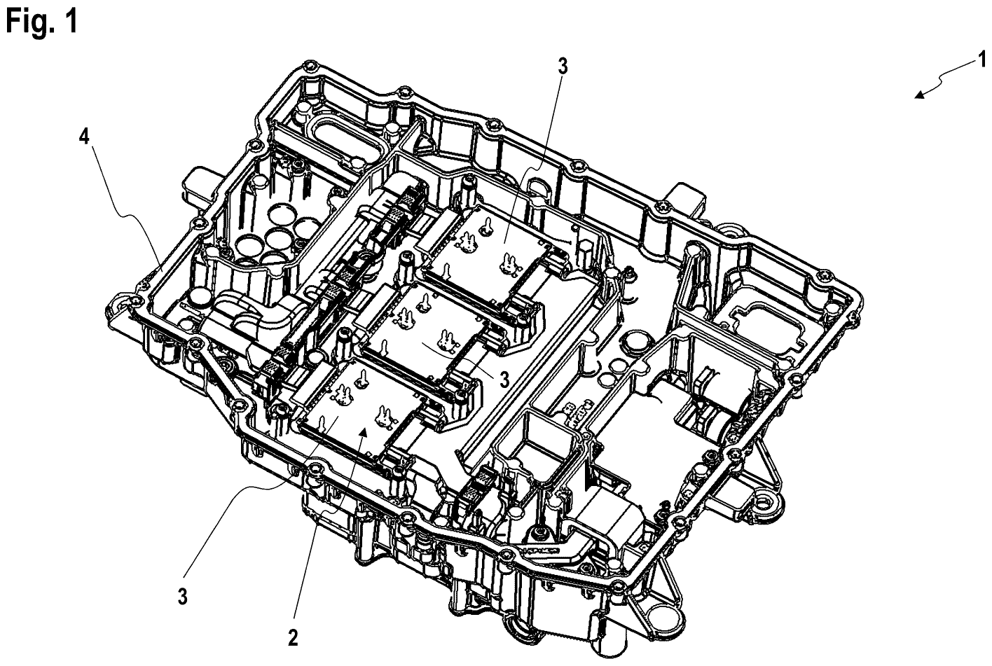

FIG. 1 a perspective view on the top of an embodiment of an inverter device according to the invention;

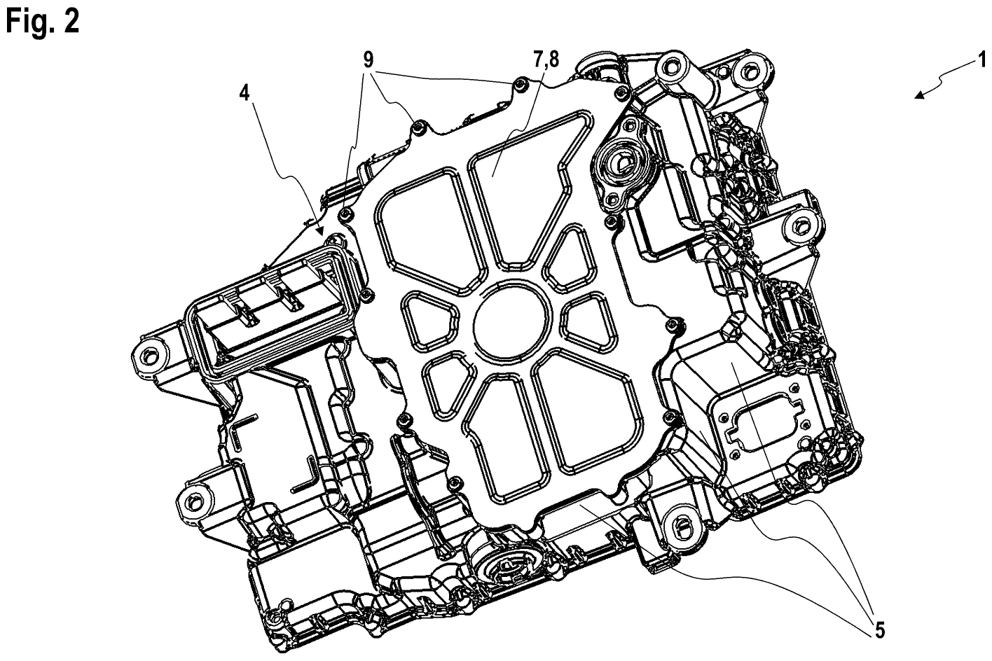

FIG. 2 a perspective view on the bottom of the inverter device shown in FIG. 1;

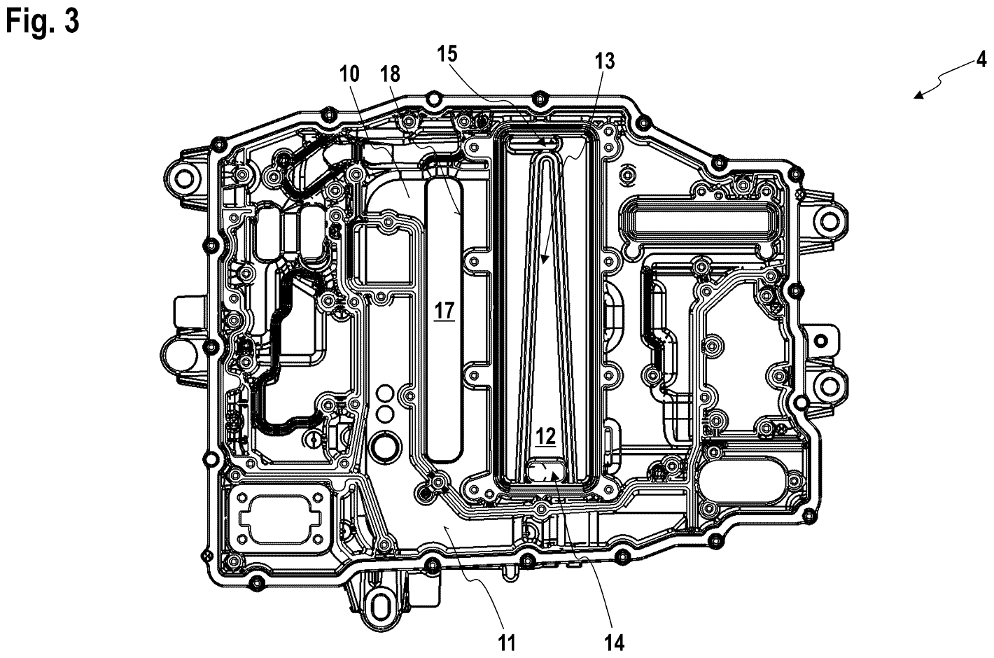

FIG. 3 a top view on a housing structure of the inverter device shown in FIG. 1;

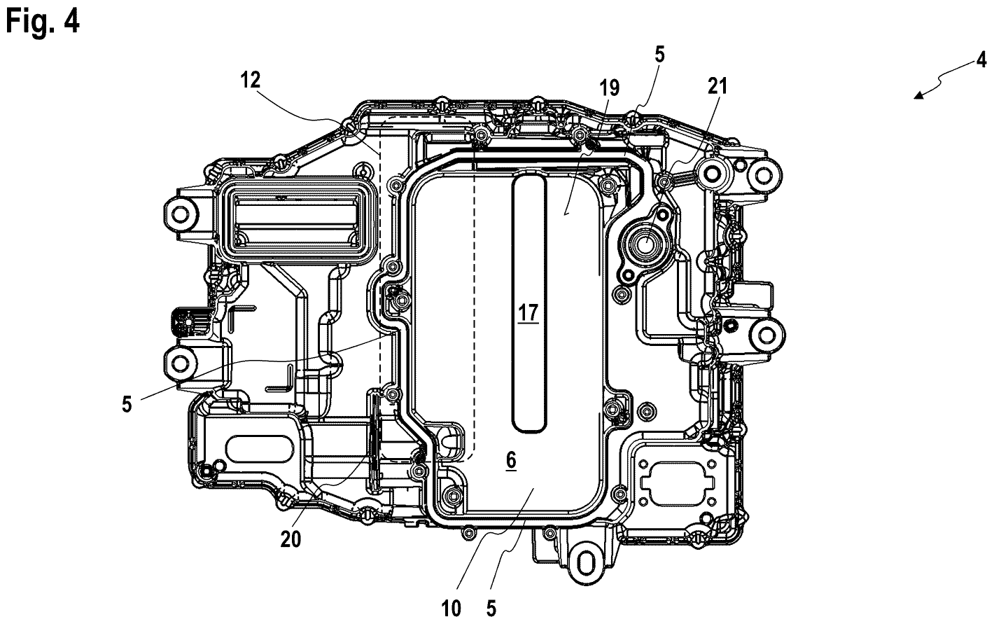

FIG. 4 a bottom view on the housing structure shown in FIG. 3;

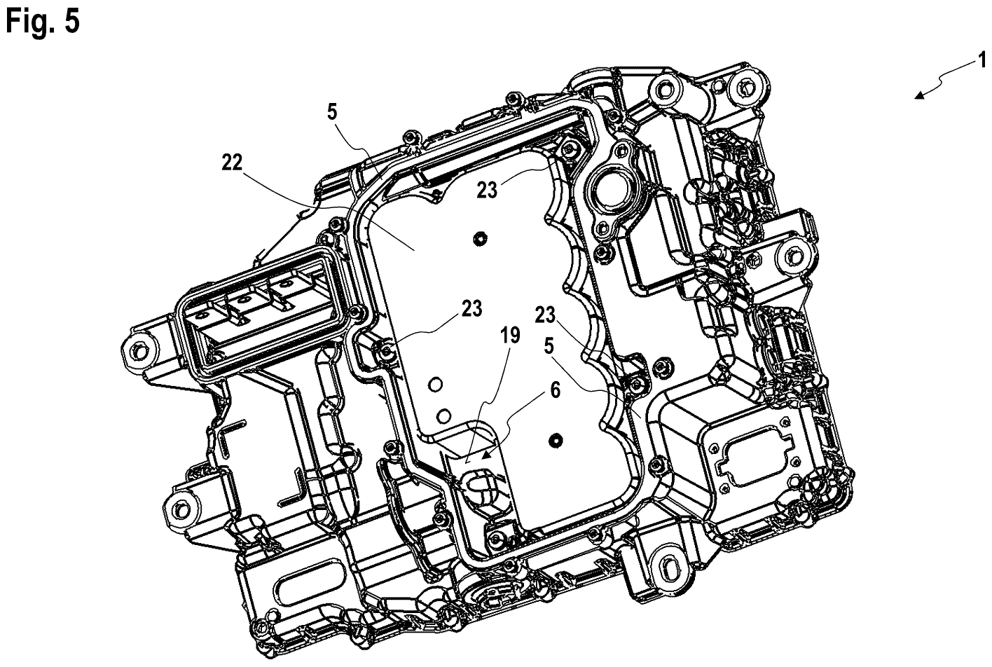

FIG. 5 a perspective view showing a capacitor assembly mounted in the inverter device shown in FIG. 1;

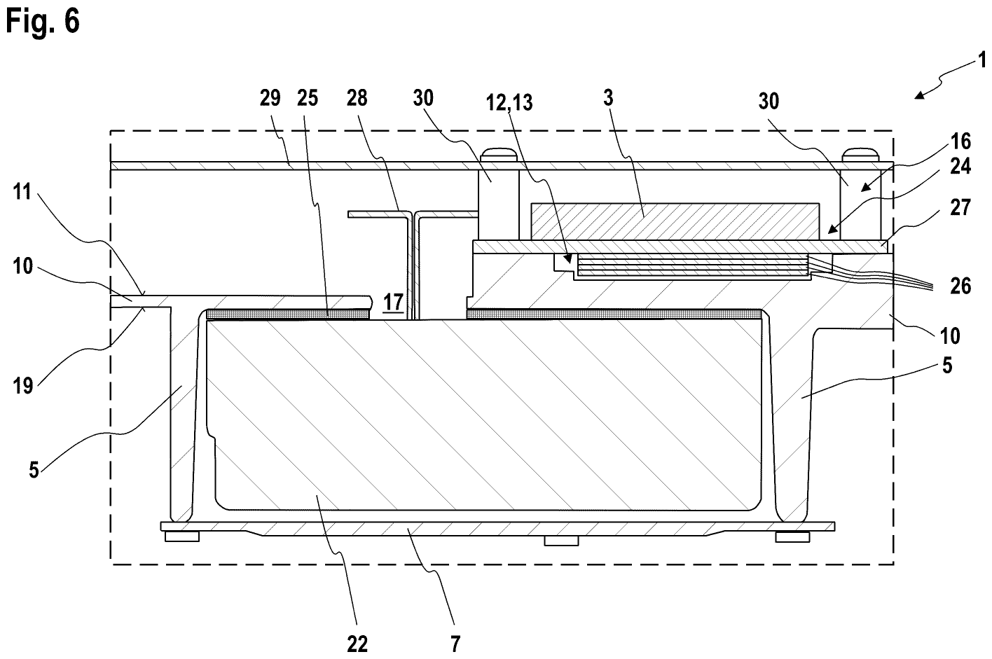

FIG. 6 a partial cross-section view of the inverter device shown in FIG. 1; and

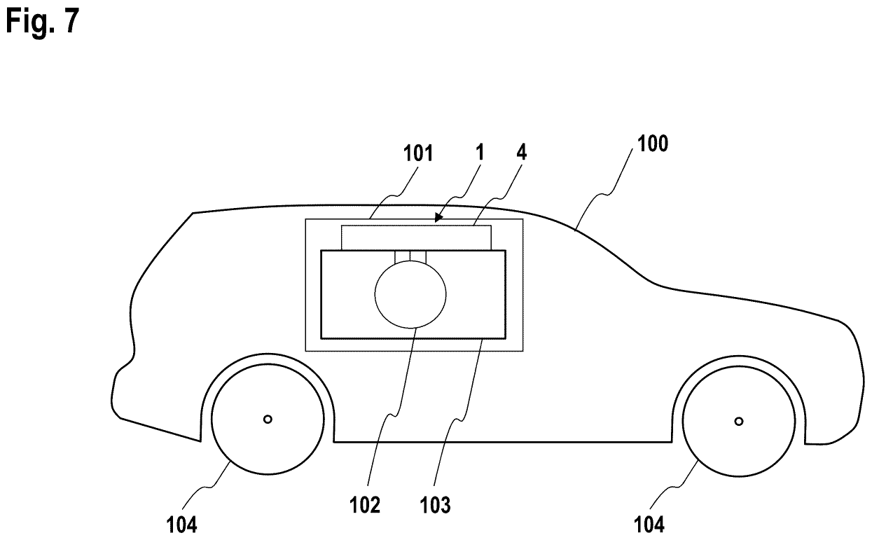

FIG. 7 a principle drawing of an embodiment of a vehicle according to the invention with an embodiment of an electric drive according to the invention;

FIG. 1 is a perspective view on the top of an embodiment of an inverter device 1. The inverter device comprises an inverter circuit 2 comprising multiple semiconductor switching modules 3. The switching modules 3 may be based on IGBT or power MOSFET components. Further, the inverter circuit 1 comprises a housing structure 4.

FIG. 2 is a perspective view on the bottom of the inverter device 1. The housing structure 4 comprises side wall sections 5 surrounding an accommodation space 6 (not visible in FIG. 2) and a base wall section 7. In the present embodiment, the base wall section 7 is formed by a cover plate 8 fastened to the side wall sections 5. For fastening the cover plate 8 to the side wall sections, the inverter device 1 is provided with screws 9.

FIG. 3 is a top view on the housing structure 4.

The housing structure 4 further comprises a top wall section 10, which limits the accommodation space 6 (not visible in FIG. 3) on the opposing side of the base wall section 8 (see FIG. 2). On a first side 11 of the top wall section 10, a cavity 12 is formed. As will be described later, the cavity 12 limits a cooling channel 13, which connects an inlet 14 and an outlet 15 of a cooling device 16 (see FIG. 6).

Further, FIG. 3 shows an opening 17 of the top wall section 10. The opening 17 is oblong and has a long side 18, which extends along a coolant main flow direction of the cooling channel 13. The coolant main flow direction is directed from the inlet 14 to the outlet 15.

FIG. 4 is a bottom view of the housing structure 4.

In FIG. 4, the accommodation space 6 limited by the top wall section 10 and the side wall sections 5 is visible, wherein a second side 19 of the top wall section can be seen. Further, the position of the cavity 12 is indicated by dashed lines, which partially overlies the accommodation space 6.

On the bottom side of the housing structure 4, the inverter device 1 comprises an inlet connector 20 for supplying the coolant and an outlet connector 21 for draining the coolant. The connectors 20, 21 are connected to the inlet 14 or outlet 15, respectively, by tubes formed within the housing structure 4.

FIG. 5 is a perspective view showing a capacitor assembly 22 mounted in the inverter device 1.

The capacitor assembly 22 forms a DC link capacitor for the inverter circuit 2 (see FIG. 1). The capacitor assembly 22 is arranged inside the accommodation space 6 such that the second side 19 faces the capacitor assembly 22. As the cavity 12 (see FIG. 3) overlies the capacitor assembly 22, the capacitor assembly 22 is in thermal contact with the coolant. As can be seen further in FIG. 5, the capacitor assembly 22 is removably fastened to the side wall sections 5 by means of screws 23.

FIG. 6 a partial cross-section view of the inverter device 1.

The cooling device 16 further comprises a heat exchange body 24, on which the semiconductor switching modules 3 are mounted for heat exchange with the coolant. Thus, the cooling device 16 cools the semiconductor switching elements 3 as well as the capacitor assembly 22, which is in thermal contact with the cooling device 16 via a heat transfer means 25, e.g. a gap filler material.

In particular detail, the semiconductor switching modules 3 are mounted on the heat exchange body 24 by soldering or sintering. Further, the heat exchange body 24 is formed by multiple stacked meander plates 26 and by a carrier plate 27 stacked on the meander plates 26. The semiconductor switching modules 3 are mounted on the carrier plate 27. The heat exchange body 24 is removably fastened upon the first side 11 of the top wall section 10 and closes the cavity 12.

Electrical connections 28 between the capacitor assembly 22 and a DC terminal of the inverter circuit 1 are guided through the opening 17.

FIG. 6 further shows a printed circuit board 29, which carries control electronic for the inverter circuit 2. The printed circuit board 29 is mounted on mounting domes 30, which are provided on the first side 11 and extend beyond the semiconductor switching modules 3.

FIG. 7 is a principle drawing of an embodiment of a vehicle 100 with an embodiment of an electric drive 101.

The electric drive 101 comprises a rotating electric machine 102, an inverter device according to the above embodiment and a machine housing 103, inside which the electric machine 102 is accommodated. The inverter device 1 is configured to supply a multiphase AC current to the electric machine 102. The housing structure 4 of the inverter device 1 is removably fastened to the machine housing 103.

The electric machine 102 is a synchronous motor, in particular a permanent magnet or electrically excited synchronous motor. Alternatively, the electric machine 102 is an induction motor.

The electric drive 101 is configured to propel the vehicle 100. The electric drive 101 is indirectly coupled to wheels 104 of the vehicle 100, e.g., via a gearbox (not shown). Alternatively, the electric drive is directly coupled to the wheels 104 and may realize a wheel hub drive.

The vehicle 100 is a battery electric vehicle or a fuel-cell supplied vehicle. Alternatively, the vehicle 100 is a hybrid vehicle and comprises an additional combustion engine (not shown).

1. Inverter device for an electric vehicle, the inverter device comprising:
a capacitor assembly;
an inverter circuit comprising multiple semiconductor switching modules;
a cooling device having an inlet for a coolant, an outlet for the coolant, a cooling channel connecting the inlet and the outlet in a fluid-conductive manner and a heat exchange body, on which the semiconductor switching modules are mounted for heat exchange with the coolant; and
a housing structure comprising multiple side wall sections surrounding an accommodation space, a base wall section closing the accommodation space on one end of the side wall sections and a top wall section limiting the accommodation space on another end of the side wall sections;
wherein a cavity is formed on a first side of the top wall section, the cavity limiting the cooling channel together with the heat exchange body; wherein the capacitor assembly is arranged inside the accommodation space such that a second side of the top wall section faces the capacitor assembly and that the cavity partially overlies the capacitor assembly; wherein the capacitor assembly is thermally connected to the cooling device by a heat transfer means arranged between the capacitor assembly and the second side of the top wall section for heat exchange with the coolant.

2. Inverter device according to claim 1, wherein
the semiconductor switching modules are mounted on the heat exchange body by soldering or sintering.

3. Inverter device according to claim 1, wherein
the heat exchange body is formed by multiple stacked meander plates and a carrier plate stacked on the meander plate, the semiconductor switching modules being mounted on the carrier plate.

4. Inverter device according to claim 1, wherein
the heat exchange body is removably fastened upon the first side of the top wall section, therein closing the cavity.

5. Inverter device according to claim 1, wherein
the capacitor assembly is removably fastened to the one or multiple of the wall sections in the accommodation space.

6. Inverter device according to claim 1, wherein
the top wall section comprises an opening, through which electrical connections between the capacitor assembly (″2) and a DC terminal of the inverter circuit are guided.

7. Inverter device according to claim 6, wherein
the opening is oblong with a long side extending in along a coolant main flow direction of cooling channel.

8. Inverter device according to claim 1,
the base wall section is realized by a cover plate removably fastened to housing structure.

9. Inverter device according to claim 1, further comprising
a printed circuit board, the semiconductor switching modules being arranged between the cavity and the printed circuit board.

10. Inverter device according to claim 9, wherein
the top wall section comprises mounting domes extending from its first side beyond the semiconductor switching modules, the printed circuit board being mounted on the mounting domes.

11. Inverter device according to claim 1, further comprising
an inlet connector for supplying the coolant and an outlet connector for draining the coolant, wherein the inlet connector is connected to the inlet of the cooling channel by tubes formed within the housing structure and/or the outlet connector is connected to the outlet of the cooling channel by tubes formed within the housing structure.

12. Electric drive for driving a vehicle, the electric drive comprising:
a rotating electric machine; and
an inverter device (according to claim 1;
wherein the inverter device (His configured to supply a multiphase AC current to the electric machine.

13. Electric drive according to claim 12, further comprising
a machine housing, inside which the electric machine is accommodated, wherein the housing structure of the inverter device is removably fastened to the machine housing.

14. Vehicle, comprising an electric drive according to claim 12.

15. Inverter device according to claim 2, wherein
the heat exchange body is formed by multiple stacked meander plates and a carrier plate stacked on the meander plate, the semiconductor switching modules being mounted on the carrier plate.

16. Inverter device according to claim 2, wherein
the heat exchange body is removably fastened upon the first side of the top wall section, therein closing the cavity.

17. Inverter device according to claim 2, wherein
the capacitor assembly is removably fastened to the one or multiple of the wall sections in the accommodation space.

18. Inverter device according to claim 2, wherein
the top wall section comprises an opening, through which electrical connections between the capacitor assembly (″2) and a DC terminal of the inverter circuit are guided.

19. Inverter device according to claim 2,
the base wall section is realized by a cover plate removably fastened to housing structure.

20. Inverter device according to claim 2, further comprising
a printed circuit board, the semiconductor switching modules being arranged between the cavity and the printed circuit board.
